(19) United States
(12) Patent Application Publication
(10) Pub. No.: US 2006/0103474 A1
(43) Pub. Date: May 18, 2006

(54) Oscillator, integrated circuit, and communication apparatus

(75) Inventor: Nobuyuki Ashida, Nara-shi (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/274,328

(22) Filed: Nov. 16, 2005

(30) Foreign Application Priority Data
Nov. 17, 2004 (JP) 2004-333593

(51) Int. Cl. H03L 7/00

(52) U.S. Cl. 331/2

(57) ABSTRACT

An oscillator of the present invention includes: (a) a plurality of voltage control oscillator circuits, each of whose oscillation frequency varies, according to a control voltage, between a lower limit frequency and an upper limit frequency; and (b) a selection circuit for selecting an arbitrary voltage control oscillator circuit from the voltage control oscillator circuits. Two or more of the voltage control oscillator circuits are different in terms of a ratio of (i) a difference between the upper limit frequency and the lower limit frequency, to (ii) an intermediate frequency between the upper limit frequency and the lower limit frequency. This allows prevention of unnecessary increase of manufacturing cost and a circuit area, and allows acquirement of an oscillator (e.g., a local oscillator) which covers a wide frequency range and which has a good phase noise property.

This Nonprovisional application claims priority under 35 U.S.C. §119(a) on Patent Application No. 2004/333593 filed in Japan on Nov. 17, 2004, the entire contents of which are hereby incorporated by reference.

### FIELD OF THE INVENTION

The present invention relates to (i) a local oscillator (LO) which can cover a continuous wide frequency range, and (ii) a communication apparatus using the local oscillator. A specific example of the communication apparatus is a satellite broadcasting accommodating receiver.

### BACKGROUND OF THE INVENTION

Television broadcasting such as satellite broadcasting, cable television broadcasting, or terrestrial broadcasting uses a wide frequency range. For example, a satellite broadcasting indoor receiver uses a frequency range from 950 MHZ to 2150 MHz. The cable television broadcasting uses a frequency range from 52 MHz to 864 MHz. For this reason, a local oscillator for use in a receiver accommodated to such broadcasting needs to operate with such a wide frequency range.

Further, such broadcasting adopts a digital communication method requiring phase modulation. For less error occurrence in communication, it is very important for the local oscillator to have a good phase noise property.

Such a local oscillator normally adopts a method for controlling, with the use of a PLL (Phase Locked Loop), a voltage control oscillator circuit (VCO) including an LC oscillator circuit having an inductor and a variable capacitor.

Explained here is a general structure of such a PLL-controlled local oscillator. See FIG. 7. A local oscillator 101 includes a reference signal oscillator circuit 103, VCOs 106, and a PLL 105. The PLL 105 includes a frequency divider 107, a frequency divider 108, a phase comparator 109, a charge pump 110, and a loop filter 112.

Each of the VCOs 106 oscillates an output signal whose frequency corresponds to an applied voltage (control voltage).

The PLL 105 compares (i) the frequency of a reference signal sent from the reference signal oscillator circuit. 103, with (ii) the frequency of the output signal sent from the VCO 106. When there is a difference between the frequencies, the PLL 105 operates to control the voltage, which is to be applied to the VCO 106, so that the difference is eliminated. In other words, the PLL 105 operates in a loop manner as follows. That is, the phase comparison is carried out in response to the oscillation of the VCO 106; and the control is carried out over the voltage to be applied to the VCO 106, in accordance with the phase comparison; and the VCO 106 oscillates according to the voltage thus controlled. The reference signal oscillator circuit 103 is, e.g., a crystalline oscillator circuit, and oscillates the signal (reference signal) having a reference frequency. The frequency divider 107 has a frequency dividing rate R, so that the frequency of the reference signal sent from the reference signal oscillator circuit 103 is divided into 1/R. The frequency divider 108 has a frequency dividing rate N, so that the frequency of the output signal sent from the VCO 106 is divided into 1/N. The phase comparator 109 compares (i) the divided frequency of the reference signal, with (ii) the divided frequency of the output signal sent from the VCO 106. When the difference is found between the divided frequencies as the result of the comparison carried out by the phase comparator 109, the charge pump 110 supplies, to the loop filter 112, a current (average direct current) corresponding to the difference (phase difference). The loop filter 112 generates the control voltage to be applied to the VCO 106, in accordance with (i) the output current supplied from the charge pump 110, and (ii) the impedance of the output current. Such a feedback loop operation causes the VCO 106 to oscillate at an oscillation frequency “f=(N/R)×the reference frequency” while the PLL 105 is in a static state.

Here, the wide frequency range from, e.g., 890 MHz to 2210 MHz can be covered by the local oscillator 101 including such VCOs 106 (e.g., 106a through 106c) having different variable frequency ranges.

Explained next is phase noise of the local oscillator using the PLL. In the local oscillator, PLL in-band noise is dominant in a frequency band (loop band) in which the PLL has a loop gain of 0 dB. On the other hand, noise of each of the VCOs is dominant outside the loop band. Actually, when a frequency in an end of the loop band, i.e., a frequency fr at which the loop gain is 0 dB is high, the noise is restrained in the loop band, but the noise is increased outside the loop band. In contrast, when the frequency fr is low, the noise is increased in the loop band, but the increase of the noise is small outside the loop band. This is illustrated in FIG. 8.

Therefore, important for attainment of a good phase noise condition in the local oscillator is that: the phase noise condition is good in the VCO, and the loop band of the PLL is set appropriately.

Disclosed in Japanese Unexamined Patent Publication Tokukai 2003-110425 (published on Apr. 11, 2003) is a structure in which variable frequency ranges covered respectively by a plurality of VCOs are so set as to be successive. Such a structure is obtained as follows. That is, the VCOs are provided in an integrated circuit in accordance with the same process, with the result that the variable frequency ranges covered respectively by the VCOs vary in the same manner. Such a conventional structure never requires more than the required number of the VCOs, but allows attainment of the local oscillator operating with the wide frequency range.

For restraint of a circuit area and manufacturing cost, the conventional structure has the minimum number of the VOCs 106 as such. Moreover, the VCOs 106 are the same in terms of a variable frequency variation ratio such that the variable frequency ranges covered respectively by the VCOs 106 are so varied in the same manner as to be successive. The wording “variable frequency variation ratio” refers to a ratio of (i) a difference between an upper limit frequency in each variable frequency range and a lower limit frequency therein, and (ii) an intermediate frequency between the lower limit frequency and the upper limit frequency. FIG. 9 illustrates a specific example of this. As shown in FIG. 9, the VCO 106a covers a variable frequency range from 890 MHz of the lower limit frequency to 1200 MHz of the upper limit frequency, so that the intermediate frequency is 1045 MHz and the variable frequency variation ratio is 0.3. The VCO 106b covers a variable frequency range from 1200 MHz of the lower limit frequency to 1630 MHz of the upper limit frequency, so that the intermediate frequency is 1415 MHz and the variable frequency variation ratio is 0.3. The VCO 106c covers a variable frequency range from 1630 MHz of the lower limit frequency to 2210 MHz of the upper limit frequency, so that the intermediate frequency is 1920 MHz and the variable frequency variation ratio is 0.3. As such, the respective variation ratios of the VCOs are the same in the local oscillator 101.

In this case, each of the VCOs should cover such a wide frequency range. This causes the oscillation frequency to greatly change according to a change of the control voltage, and a frequency property of a circuit element makes it difficult to obtain large oscillation amplitude. This causes great deterioration of the phase noise property, especially in the VCO 106c covering the high frequencies.

In cases where the larger number of VCOs each having a smaller variable frequency variation ratio are used to avoid this, the circuit scale and the manufacturing cost are increased. In other words, providing such VCOs individually causes increase of (i) the number of parts and (ii) an installation area, with the result that the manufacturing cost is increased. On the other hand, integrating the VCOs in a semiconductor causes increase of the number of passive elements each occupying a large area, with the result that a chip area and the manufacturing cost are increased. Examples of such passive elements include: a spiral inductor and a variable capacitor.

### SUMMARY OF THE INVENTION

The present invention is made in light of the foregoing problems, and its object is to provide an oscillator (e.g., a local oscillator LO) which has a good phase noise property and which allows restraint of the circuit area.

To achieve the object, an oscillator of the present invention includes: (a) a plurality of voltage control oscillator circuits, each of whose oscillation frequency varies, according to a control voltage, between a lower limit frequency and an upper limit frequency; and (b) a selection circuit for selecting an arbitrary voltage control oscillator circuit from the voltage control oscillator circuits, two or more of the voltage control oscillator circuits being different in terms of a ratio (a difference between the upper limit frequency and the lower limit frequency/an intermediate frequency of the upper limit frequency and the lower limit frequency) of (i) a difference between the upper limit frequency and the lower limit frequency, to (ii) an intermediate frequency between the upper limit frequency and the lower limit frequency.

The voltage control oscillator circuits of the oscillator cover, e.g., different variable frequency ranges as such. This makes it possible to select a voltage control oscillator circuit corresponding to a desired frequency. Accordingly, a wide frequency range can be covered.

According to the structure above, two or more of the voltage control oscillator circuits are different in terms of the ratio (the difference between the upper limit frequency and the lower limit frequency/the intermediate frequency of the upper limit frequency and the lower limit frequency) of (i) the difference between the upper limit frequency and the lower limit frequency, to (ii) the intermediate frequency between the upper limit frequency and the lower limit frequency. In other words, it is possible to arbitrarily set the ratio (the difference between the upper limit frequency and the lower limit frequency/the intermediate frequency of the upper limit frequency and the lower limit frequency) according to the frequency range covered by each of the voltage control oscillator circuits.

So, an oscillator having a good phase noise property can be obtained by setting the ratio at low for a voltage control oscillator covering a frequency range in which it is difficult to obtain a good phase noise property, and by setting the ratio at high for a voltage control oscillator covering a frequency range in which it is easy to obtain the good phase noise property. The oscillator thus obtained allows restraint of the circuit area and the manufacturing cost.

Additional objects, features, and strengths of the present invention will be made clear by the description below. Further, the advantages of the present invention will be evident from the following explanation in reference to the drawings.

### BRIEF DESCRIPTION OF THE DRAWINGS

FIG. 1 is a table illustrating a variable frequency variation ratio of each of VCOs provided in each local oscillator according to the present invention.

FIG. 2 is a block diagram illustrating a structure of a local oscillator according to Embodiment 1 of the present invention.

FIG. 3 is a block diagram illustrating a structure of a local oscillator according to Embodiment 2 of the present invention.

FIG. 4 is a table illustrating a correlation between (i) a variable frequency range covered by each VCO of the local oscillator shown in FIG. 3, and (ii) an output current of a charge pump.

FIG. 5 is a block diagram illustrating a structure of a local oscillator according to Embodiment 3 of the present invention.

FIG. 6 is a table illustrating a correlation between (i) a variable frequency range covered by each VCO of the local oscillator shown in FIG. 5, and (ii) a comparison frequency.

FIG. 7 is a block diagram illustrating a structure of a conventional local oscillator.

FIG. 8 is an explanatory diagram illustrating a relation between a loop band of a PLL-controlled VCO and phase noise.

FIG. 9 is a table illustrating a variation frequency variation ratio in each VCO provided in the local oscillator shown in FIG. 7.

### DESCRIPTION OF THE EMBODIMENTS

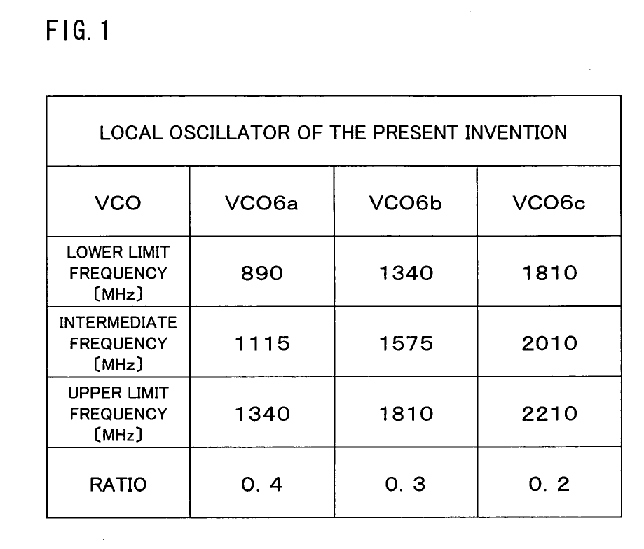

The following explains embodiments of a local oscillator (oscillator) according to the present invention, with reference to FIG. 1 through FIG. 6. Note that each of the embodiments assumes a case where a frequency range from 890 MHz to 2210 MHz is covered by three VCOs (voltage control oscillator circuits). For the purpose of entirely covering the frequencies even when oscillation frequencies vary absolutely or relatively, it is preferable to design the VCOs such that an upper limit frequency handled by a VCO overlaps with a lower limit frequency handled by another VCO. However, for ease of explanation, the following never takes this into consideration, i.e., the following has no description about this.

### Embodiment 1

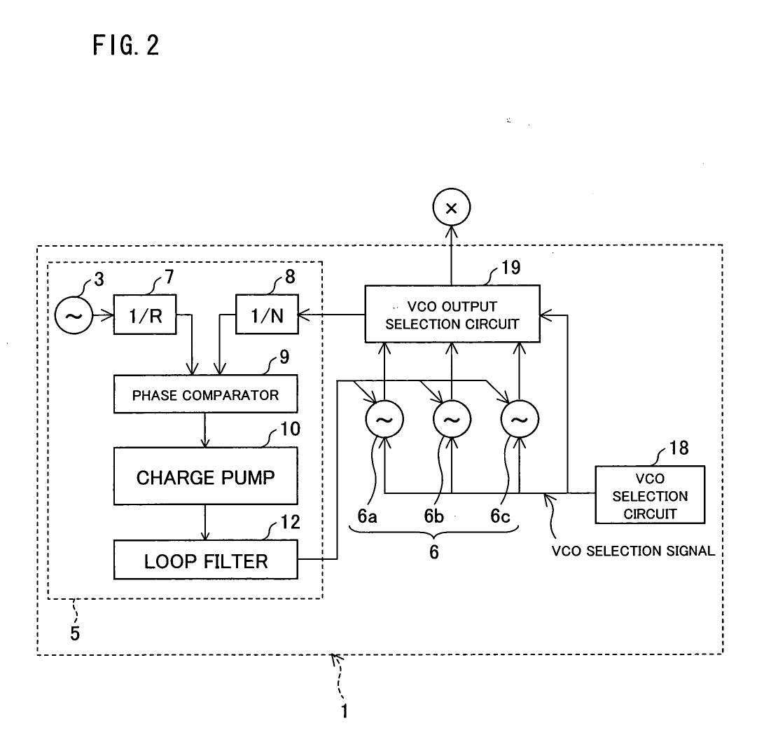

FIG. 2 is a block diagram illustrating a local oscillator 1 (oscillator) according to Embodiment 1. As shown in FIG. 2, the local oscillator 1 includes: three VCOs 6a through 6c (voltage control oscillator circuits); a PLL 5, a VCO selection circuit 18 (selection circuit); and a VCO output selection circuit 19. The PLL 5 includes a frequency divider 7, a frequency divider 8, a frequency comparator 9, a charge pump 10, and a loop filter 12.

Each of the VCOs 6a through 6c oscillates, according to an applied voltage (control voltage), a signal having a frequency ranging from a lower limit frequency to an upper limit frequency, i.e., a signal having a frequency falling within a variable frequency range. Here, the VCOs 6a through 6c cover different variable frequency ranges (variable frequency ranges that never overlap with one another). The VCO selection circuit 18 outputs a VCO selection signal such that: only a VCO, which oscillates at a desired frequency, of the VCOs 6a through 6c operates, and the other VCOs stop operating. The VCO output selection circuit 19 sends, to outside such as a mixer, a signal supplied from the selected VCO, i.e., the VCO having received the VCO selection signal. As such, the VCOs in the local oscillator 1 are switched according to a required frequency, so that the wide frequency range can be covered.

The PLL 5 controls the voltage to be applied to the VCO 6, i.e., the selected one of the VCOs 6a through 6c, in accordance with the frequency of a reference signal and the frequency of the output signal of the VCO 6. In other words, the PLL 5 operates in a loop manner as follows. That is, a phase comparison is carried out between the signals in response to the oscillation of the VCO 6; and the control is carried out over the voltage to be applied to the VCO 6, in accordance with the phase comparison; and the VCO 6 oscillates according to the voltage thus controlled.

The reference signal oscillator circuit 3 is, e.g., a crystalline oscillator circuit, and oscillates the signal (reference signal) having a reference frequency. The frequency divider 7 has a frequency dividing rate R, so that the frequency of the reference signal sent from the reference signal oscillator circuit 3 is divided into 1/R. The frequency divider 8 has a frequency dividing rate N, so that the frequency of the output signal sent from the VCO 6 is divided into 1/N. The phase comparator 9 compares (i) the divided frequency of the reference signal, with (ii) the divided frequency of the output signal sent from the VCO 106. When a difference is found between the divided frequencies as the result of the comparison carried out by the phase comparator 9, the charge pump 10 supplies, to the loop filter 12, a current (average direct current) corresponding to the difference (phase difference). The loop filter 12 generates the control voltage to be applied to the VCO 6, in accordance with (i) the output current supplied from the charge pump 10, and (ii) the impedance of the output current. Such a feedback loop operation causes the VCO 6 to oscillate at an oscillation frequency “f=(N/R)×the reference frequency” while the PLL 5 is in a static state.

FIG. 1 illustrates (i) the variable frequency range of each of the VCOs and (ii) the variation ratio (variable frequency variation ratio) of the variable frequency range, in the present embodiment. This is one design example in which the three VCOs 6a through 6c cover the frequency range from 890 MHz to 2210 MHz.

As shown in FIG. 1, the respective variable frequency variation ratios of the VCOs are different in the local oscillator 1. The wording “variable frequency variation ratio” refers to a ratio of (i) a difference (frequency variation amplitude) between the upper limit frequency and the lower limit frequency, to (ii) an intermediate frequency (center frequency) of the upper limit frequency and the lower limit frequency. Specifically, the VCO 6a covers a variable frequency range from 890 MHz of the lower limit frequency to 1340 MHz of the higher limit frequency, so that the intermediate frequency is 1115 MHz and the variable frequency variation ratio is 0.4. The VCO 6b covers a variable frequency range from 1340 MHz of the lower limit frequency to 1810 MHz of the higher limit frequency, so that the intermediate frequency is 1575 MHz and the variable frequency variation ratio is 0.3. The VCO 6c covers a variable frequency range from 1810 MHz of the lower limit frequency to 2210 MHz of the higher limit frequency, so that the intermediate frequency is 2010 MHz and the variable frequency variation ratio is 0.2.

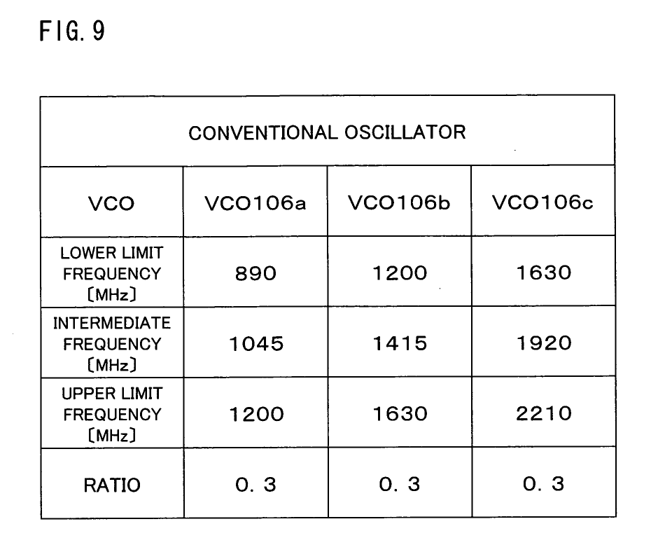

As described above, in the conventional structure shown in FIG. 9, the respective variable frequency variation ratios are the same (identical) among the VCOs.

Here, see a comparison between (i) the phase noise of each VCO of the present embodiment, and (ii) the phase noise of each VCO of the conventional structure. Firstly described is a comparison between (i) the phase noise of the VCO 6c whose lower limit frequency is the highest and whose variation ratio of the variable frequency range is 0.2, and (ii) the phase noise of the VCO 106c whose variation ratio of the variable frequency range is 0.3. The comparison clarifies that the VCO 6c of the present embodiment, i.e., the VCO 6c having the variation ratio different from that of the VCO 106c allows attainment of a good phase noise condition. Meanwhile, see a comparison between (i) the phase noise in the VCO 6a whose lower limit frequency is the lowest and whose variation ratio of the variable frequency range is 0.4, and (ii) the phase noise in the VCO 106a whose variation ratio of the variation frequency range is 0.3. The comparison clarifies that the conventional VCO 106a allows attainment of a good phase noise condition. However, the local oscillator 1 allows great improvement of the worst phase noise condition, i.e., the phase noise condition in the frequency range covered by the VCO 6c (106c). Accordingly, the phase noise condition can be improved in the entire local oscillator 1, as compared with the conventional structure in which the variation ratios of the variable frequency ranges are the same as shown in FIG. 9.

For the purpose of minimizing an influence of the phase noise of the VCO 6a whose lower limit frequency is the lowest, it is preferable to set each of the variable frequency ranges of the VCOs (VCOs 6a through 6c) and each of the variation ratios thereof such that the phase noise property of the local oscillator is maximally improved.

### Embodiment 2

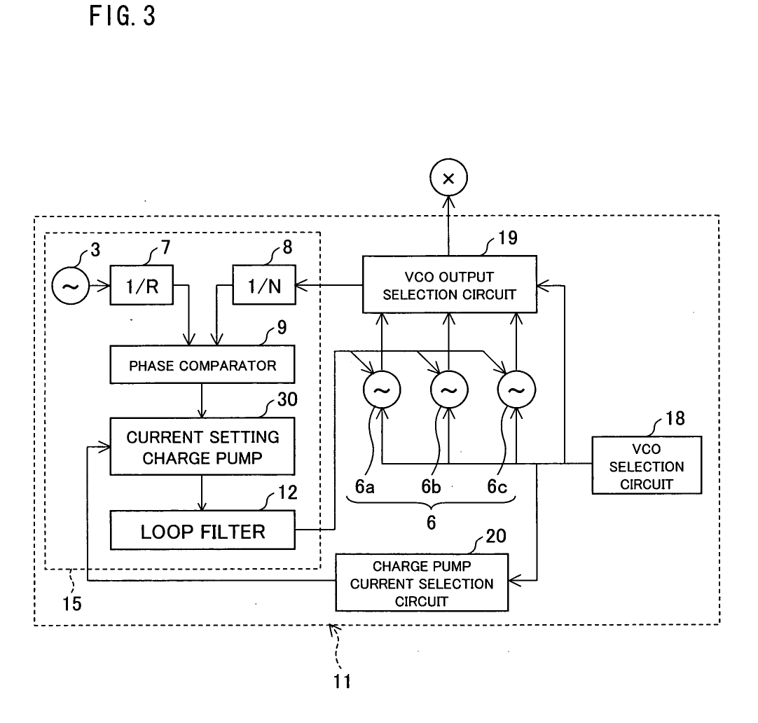

FIG. 3 is a block diagram illustrating a structure of a local oscillator 11 according to Embodiment 2. As shown in FIG. 3, the local oscillator 11 includes the VCOs 6a through 6c, a PLL 15, the VCO selection circuit 18, the VCO output selection circuit 19, and a charge pump current selection circuit 20 (output setting means). The PLL 15 includes the reference signal oscillator circuit 3, the frequency divider 7, the frequency divider 8, the phase comparator 9, a current setting charge pump 30, and the loop filter 12.

Therefore, the difference between the local oscillator 11 according to the present embodiment and the structure of Embodiment 1 lies in that: the local oscillator 11 includes the charge pump current selection circuit 20 and the PLL 15 provided with the current setting charge pump 30 whose output current is settable. Except this, the structure of the local oscillator 11 is the same as that of Embodiment 1.

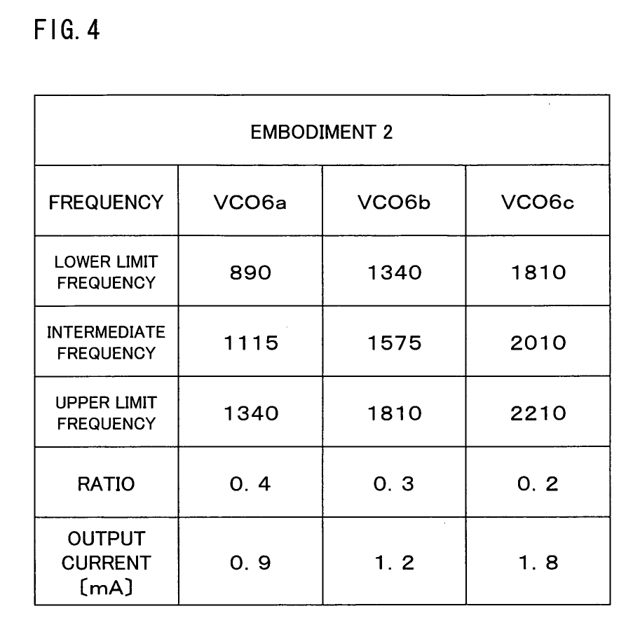

When receiving the VCO selection signal from the VCO output selection circuit 19, the charge pump current selection circuit 20 determines and sets the output current which corresponds to each of the VCOs and which is to be supplied from the current setting charge pump 30. FIG. 4 illustrates one design example in which the charge pump 30 outputs the current corresponding to the variable frequency range of each of the VCOs. As shown in FIG. 4, the VCO 6a covers the variable frequency range from 890 MHz of the lower limit frequency to 1340 MHz of the upper limit frequency, so that the variable frequency variation ratio is 0.4, and the output current of the charge pump 30 is 0.9 mA. The VCO 6b covers the variable frequency range from 1340 MHz of the lower limit frequency to 1810 MHz of the upper limit frequency, so that the variable frequency variation ratio is 0.3, and the output current of the charge pump 30 is 1.2 mA. The VCO 6c covers the variable frequency range from 1810 MHz of the lower limit frequency to 2210 MHz of the upper limit frequency, so that the variable frequency variation ratio is 0.2, and the output current of the charge pump 30 is 1.8 mA.

As such, the VCOs 6a through 6c have the same product of the variable frequency variation ratio and the output current of the charge pump 30. This makes it possible for the loop filter 12 to constantly maintain a loop gain of the PLL 15 even when any VCO 6 is selected.

Note that, the local oscillator 11 can be arranged such that: in order to determine the output current of the charge pump 30, the charge pump current selection circuit 20 accesses a memory section (not shown) which stores a relation between the selected VCO and the output current of the charge pump 30, and which is provided inside or outside the local oscillator 11. The access is carried out in response to the receipt of the VCO signal.

Further, even when any VCO is selected, a good phase noise property can be obtained by designing the PLL 15 such that the PLL 15 has a loop gain allowing the local oscillator 11 to have the best phase noise property.

Note that the charge pump 30 whose output current is settable can be realized with ease by, e.g., changing the number of current mirror circuits which are provided in a charge pump, and which are used to extract a current from a reference current source (not shown), and which are connected to an output terminal and connected in parallel with each other. Further, the charge pump current selection circuit 20 can be realized easily with the use of a combinational circuit for receiving the VCO selection signal.

### Embodiment 3

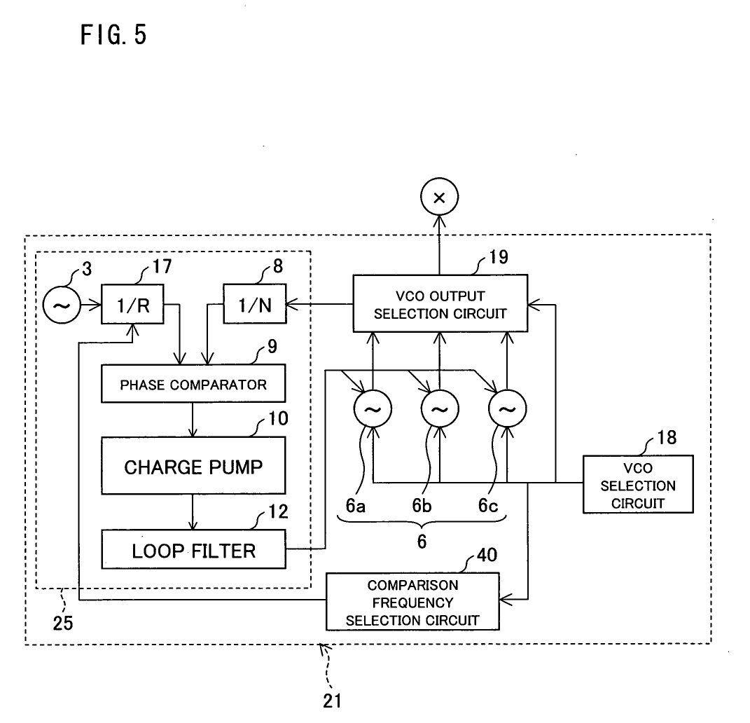

FIG. 5 is a block diagram illustrating a structure of a local oscillator 21 according to Embodiment 3. As shown in FIG. 5, the local oscillator 21 includes the VCOs 6a through 6c, a PLL 25, the VCO selection circuit 18, and the VCO output selection circuit 19, and a comparison frequency selection circuit 40 (frequency dividing rate setting means). The PLL 25 includes the reference signal oscillator circuit 3, a variable frequency dividing rate frequency divider 17, the frequency divider 8, the phase comparator 9, the charge pump 10, and the loop filter 12.

Therefore, the difference between the local oscillator 21 according to the present embodiment and the structure of Embodiment 1 lies in that: the local oscillator 21 includes the comparison frequency selection circuit 40 and the PLL 25 provided with the variable frequency dividing rate frequency divider 17 whose frequency dividing rate is settable. Except this, the structure of the local oscillator 21 is the same as that of Embodiment 1.

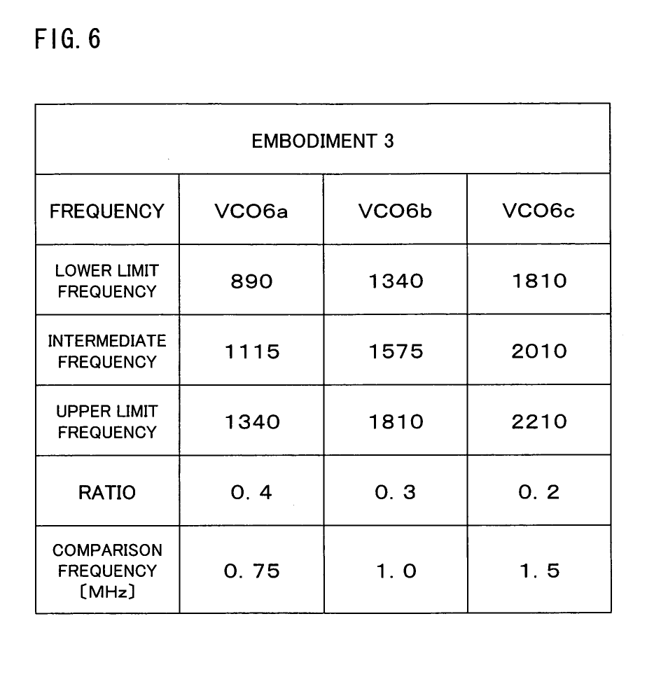

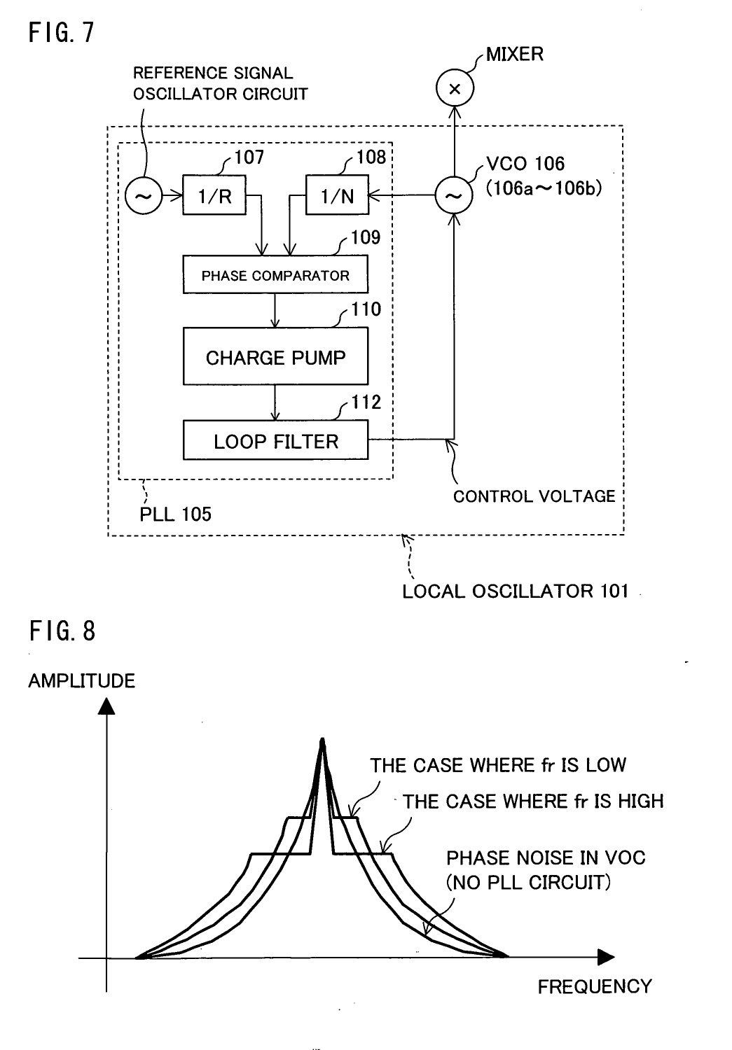

When receiving the VCO selection signal, the comparison frequency selection circuit 40 determines a comparison frequency (frequency obtained by dividing the frequency of the reference signal) corresponding to the selected VCO. Then, the comparison frequency selection circuit 40 sets the frequency dividing rate of the variable frequency dividing rate frequency divider 17 such that the variable frequency dividing rate frequency divider 17 outputs a signal having the comparison frequency thus determined. FIG. 6 illustrates one design example in which the comparison frequency corresponds to the variable frequency range of each VCO. As shown in FIG. 6, the VCO 6a covers the variable frequency range from 890 MHz of the lower limit frequency to 1340 MHz of the upper limit frequency, so that the variable frequency variation ratio is 0.4, and the comparison frequency is 0.75 MHz. The VCO 6b covers the variable frequency range from 1340 MHz of the lower limit frequency to 1810 MHz of the upper limit frequency, so that the variable frequency variation ratio is 0.3, and the comparison frequency is 1.0 MHz. The VCO 6c covers the variable frequency range from 1810 MHz of the lower limit frequency to 2210 MHz of the upper limit frequency, so that the variable frequency variation ratio is 0.2, and the comparison frequency is 1.5 MHz.

As such, the VCOs 6a through 6c have the same product of the variable frequency variation ratio and the comparison frequency. This makes it possible for the loop filter 12 to constantly maintain a loop gain of the PLL 25 even when any VCO is selected.

Further, even when any VCO is selected, a good phase noise property can be obtained by designing the PLL 25 such that the PLL 25 has a loop gain allowing the local oscillator 21 to have the best phase noise property.

Note that, the local oscillator 21 can be arranged such that: in order to set the frequency dividing rate of the variable frequency dividing rate frequency divider 17, the comparison frequency selection circuit 40 accesses a memory section (not shown) which stores a relation between the selected VCO and the comparison frequency (corresponding frequency dividing rate), and which is provided inside or outside the local oscillator 21. The access is carried out in response to the receipt of the VCO signal.

Further, the variable frequency dividing rate frequency divider 17 can be realized with ease by using a divider which serves as counter circuit, and which includes a flip-flop circuit, and whose count number is changeable.

Further, the comparison frequency selection circuit 40 can be realized easily with the use of a combinational circuit for receiving the VCO selection signal. Note that the oscillation frequency which can be set in the PLL is limited to a frequency obtained by multiplying the comparison frequency by an integer. For this reason, the comparison frequency needs to be set appropriately according to a required frequency.

Note that Embodiments 2 and 3 are separately explained; however, the respective structures of Embodiments 2 and 3 can be combined as required. Specifically, when the output current of the charge pump is used together with the comparison frequency, the loop gain can be optimized more flexibly, with the result that a good phase noise property can be obtained.

Further, each of the local oscillators 1, 11, and 21 according to the respective embodiments can be integrated in a semiconductor, i.e., in an integrated circuit. This allows downsizing and cost reduction as compared with a case where these members are provided individually. Further, it is difficult to provide, in such an integrated circuit, a passive element having a large Q value. This makes it difficult to obtain a good phase noise condition. In this respect, the present invention exhibits a great effect.

Note that the above explanation describes the specific number of the VOCs 6 and the specific variable frequency variation ratios; however, the present invention are not limited to these. It is desirable to optimize the number of the VCOs 6, the allocation of the variable frequency ranges to the VCOs 6 (the setting of the variation ratio in each of the VCOs 6), the output current of the charge pump, the comparison frequency, and the like such that the best phase noise property can be obtained in a required frequency range with the use of the minimum number of the VCOs 6. The attainment of the best phase noise property is done by experimentally and analytically finding the phase noise property, which corresponds to the variable frequency range (the variation ratio), of each of the VCOs 6.

As described above, each of the local oscillators (1, 11, and 21) includes the plurality of VCOs (6a through 6c), and the VCOs are different in terms of the ratio of (i) the difference between the upper limit frequency in the variable frequency range and the lower limit frequency therein, to (ii) the intermediate frequency between the upper limit frequency and the lower limit frequency.

Therefore, the ratio (the ratio of (i) the difference between the upper limit frequency and the lower limit frequency, to (ii) the intermediate frequency between the upper limit frequency and the lower limit frequency) can be changed according to the frequency range covered by each of the VCOs. With this, an oscillator having a good phase noise property can be obtained by setting the ratio at low for a VCO covering a frequency range in which it is difficult to obtain a good phase noise property, and by setting the ratio at high for a VCO covering a frequency range in which it is easy to obtain the good phase noise property. The oscillator thus obtained allows restraint of the circuit area and the manufacturing cost.

Further, each of the local oscillators (1, 11, and 21) is arranged such that the ratio is smaller in a voltage control oscillator circuit whose lower limit frequency is higher.

The structure above makes it possible to improve phase noise in the VCO (e.g., the VCO 6c) covering the high frequency range in which it is difficult to obtain a good phase noise property. Further, a wide frequency range (e.g., 890 MHz through 2210 MHz) can be covered by setting the ratio at high for the VCO (e.g., the VCO 6a) covering the low frequency range in which it is easy to obtain a good phase noise property. This makes it possible for each of the local oscillators (1, 11, and 21) to cover such a wide frequency range, and to have a good phase noise property.

The local oscillator 11 includes: (i) the charge pump 30, which constitutes a PLL 15 and whose output current is variable; and (ii) the charge pump current selection circuit 20 for setting the output current of the charge pump 30 such that the output current corresponds to the selected VCO 6.

According to the structure above, the loop gain of the PLL 15 can be optimized by setting the output current of the charge pump 30 in accordance with the ratio of each of the VCOs 6. This makes it possible to obtain a good phase noise condition in the entire local oscillator 11.

The local oscillator 11 is arranged such that the charge pump current selection circuit 20 sets a larger current to be outputted, as the ratio is smaller in a voltage control oscillator circuit.

According to the structure above, the loop gain of the PLL 15 can be maintained constantly even when any of the VCOs 6 is selected. This makes it possible to obtain a good phase noise condition in the entire local oscillator 11.

Further, it is preferable that the local oscillator 11 further include: a memory section for storing a relation between the selected VCO 6 and the output current of the charge pump 30.

According to the structure above, the selection of the VCO 6 and the setting of the output current of the charge pump 30 do not need to be carried out separately. Therefore, no setting circuit needs to be provided for the VCO 6 and the PLL 15. This makes it possible that: the local oscillator 11 has the function of setting the output current of the charge pump, and the circuit area and the manufacturing cost are restrained.

The local oscillator 21 further includes: (i) the frequency divider 17, which constitutes the PLL 25 and whose frequency dividing rate is variable; and (ii) the comparison frequency selection circuit 40 for setting the frequency dividing rate of the frequency divider such that frequency dividing rate corresponds to the selected VCO.

According to the structure above, the loop gain of the PLL 25 can be optimized by varying (setting) the frequency dividing rate of the frequency divider 17 in accordance with the ratio of each of the VCOs 6. This makes it possible to obtain a good phase noise condition in the entire local oscillator 21.

The local oscillator 21 is arranged such that the comparison frequency selection circuit 40 sets a smaller frequency dividing rate, as the ratio is smaller in a VCO (i.e., the comparison frequency selection circuit 40 causes the comparison frequency to be higher).

According to the structure above, the loop gain of the PLL 25 can be maintained constantly even when any of the VCOs 6 is selected. This makes it possible to obtain a good phase noise condition in the entire local oscillator 21.

It is preferable that the local oscillator 21 further include: a memory section for storing a relation between the selected VCO and the frequency dividing rate of the frequency divider 17.

According to the structure above, the selection of the VCO 6 and the setting of the frequency dividing rate of the frequency divider 17 do not need to be carried out separately. Therefore, no setting circuit needs to be provided for the VCO 6 and the PLL 25. This makes it possible that: the local oscillator 11 has the function of setting the frequency dividing rate of the frequency divider, and the circuit area and the manufacturing cost are restrained.

Note that, it is possible to express that each of the local oscillators (1, 11, and 21) according to the present embodiments is a local oscillator, which includes a plurality of VCOs (6a through 6c) which cover different oscillation frequency ranges (variable frequency ranges), and which covers a desired frequency range (e.g., 890 MHz to 2210 MHz) by switching, according to a required frequency, the VCOs to be in use, wherein: the VCOs are different in terms of a variation ratio of variable frequency (range).

As described above, each of the present embodiments makes it possible to obtain an oscillator (e.g., local oscillator) which never unnecessarily increases the manufacturing cost and the circuit area, and which covers a wide frequency range, and which has a good phase noise property.

It is preferable to arrange the oscillator such that the ratio (the difference between the upper limit frequency and the lower limit frequency/the intermediate frequency between the upper limit frequency and the lower limit frequency) is smaller in a voltage control oscillator circuit whose lower limit frequency is higher.

The structure above makes it possible to improve phase noise in a voltage control oscillator circuit covering a high frequency range in which it is difficult to obtain a good phase noise property. Further, a wide frequency range can be covered by setting the ratio at high for a voltage control oscillator circuit covering a low frequency range in which it is easy to obtain a good phase noise property. This makes it possible for the oscillator to cover such a wide frequency range, and to realize a good phase noise property.

Further, it is preferable that the oscillator further include: (i) a charge pump, which constitutes a PLL and whose output current is variable; and (ii) output setting circuit for setting the output current of the charge pump such that the output current corresponds to the selected voltage control oscillator circuit.

According to the structure above, the loop gain of the PLL can be optimized by setting the output current of the charge pump in accordance with the ratio of each of the voltage control oscillator circuits. This makes it possible to obtain a good phase noise condition in the entire oscillator.

Further, it is preferable to arrange the oscillator such that: the output setting circuit sets a larger current to be outputted, as the ratio (the difference between the upper limit frequency and the lower limit frequency/the intermediate frequency between the upper limit frequency and the lower limit frequency) is smaller in a voltage control oscillator circuit.

According to the structure above, the loop gain of the PLL can be maintained constantly even when any of the voltage control oscillator circuits is selected. This makes it possible to obtain a good phase noise condition in the entire oscillator.

Further, it is preferable that the oscillator further include: a memory section for storing a relation between the selected voltage control oscillator circuit and the output current of the charge pump.

According to the structure above, the selection of the voltage control oscillator circuit and the setting of the output current of the charge pump do not need to be carried out separately. Therefore, no setting circuit needs to be provided for the voltage control oscillator circuit and the PLL. This makes it possible that: the oscillator has the function of setting the output current of the charge pump, and the circuit area and the manufacturing cost are restrained.

It is preferable that the oscillator further include: (i) a frequency divider, which constitutes a PLL and whose frequency dividing rate (integer) is variable; and (ii) frequency dividing rate setting circuit for setting the frequency dividing rate of the frequency divider such that frequency dividing rate corresponds to the selected voltage control oscillator circuit. Note that the frequency divider divides a frequency of an input signal by the frequency dividing rate.

According to the structure above, the loop gain of the PLL can be optimized by varying (setting) the frequency dividing rate of the frequency divider in accordance with the ratio of each of the voltage control oscillator circuits. This makes it possible to obtain a good phase noise condition in the entire oscillator.

Further, it is preferable to arrange the oscillator such that: the frequency dividing rate setting circuit sets a smaller frequency dividing rate, as the ratio (the difference between the upper limit frequency and the lower limit frequency/the intermediate frequency between the upper limit frequency and the lower limit frequency) is smaller in a voltage control oscillator circuit (i.e., the frequency dividing rate setting circuit causes the comparison frequency to be higher).

According to the structure above, the loop gain of the PLL can be maintained constantly even when any of the voltage control oscillator circuits is selected. This makes it possible to obtain a good phase noise condition in the local oscillator.

Further, it is preferable that the oscillator further include: a memory section for storing a relation between the selected voltage control oscillator circuit and the frequency dividing rate of the frequency divider.

According to the structure above, the selection of the voltage control oscillator circuit and the setting of the frequency dividing rate of the frequency divider do not need to be carried out separately. Therefore, no setting circuit needs to be provided for the voltage control oscillator circuit and the PLL. This makes it possible that: the oscillator has the function of setting the frequency dividing rate of the frequency divider, and the circuit area and the manufacturing cost are restrained.

Further, an integrated circuit of the present embodiment includes the aforementioned oscillator. Providing the oscillator in the integrated circuit allows further downsizing of the oscillator.

Further, a communication apparatus of the present embodiment uses the oscillator.

The local oscillator according to the present embodiment is widely applicable to a communication apparatus having a RF circuit; or the like. A specific example of the communication apparatus is a satellite broadcasting accommodating receiver.

The embodiments and concrete examples of implementation discussed in the foregoing detailed explanation serve solely to illustrate the technical details of the present invention, which should not be narrowly interpreted within the limits of such embodiments and concrete examples, but rather may be applied in many variations within the spirit of the present invention, provided such variations do not exceed the scope of the patent claims set forth below.

What is claimed is:

1. An oscillator, comprising:
a plurality of voltage control oscillator circuits, each of whose oscillation frequency varies, according to a control voltage, between a lower limit frequency and an upper limit frequency; and
a selection circuit for selecting an arbitrary voltage control oscillator circuit from the voltage control oscillator circuits,
two or more of the voltage control oscillator circuits being different in terms of a ratio of (i) a difference between the upper limit frequency and the lower limit frequency, to (ii) an intermediate frequency between the upper limit frequency and the lower limit frequency.

2. The oscillator as set forth in claim 1, wherein:
the ratio is smaller in a voltage control oscillator circuit whose lower limit frequency is higher.

3. The oscillator as set forth in claim 1, further comprising:
a charge pump, which constitutes a PLL and whose output current is variable; and
output setting circuit for setting the output current of the charge pump such that the output current corresponds to the selected voltage control oscillator circuit.

4. The oscillator as set forth in claim 3, wherein:
the output setting circuit sets a larger current to be outputted, as the ratio is smaller in a voltage control oscillator circuit.

5. The oscillator as set forth in claim 3, further comprising:
a memory section for storing a relation between the selected voltage control oscillator circuit and the output current of the charge pump.

6. The oscillator as set forth in claim 1, further comprising:
a frequency divider, which constitutes a PLL and whose frequency dividing rate is variable; and
frequency dividing rate setting circuit for setting the frequency dividing rate of the frequency divider such that the frequency dividing rate corresponds to the selected voltage control oscillator circuit.

7. The oscillator as set forth in claim 6, wherein:
the frequency dividing rate setting circuit sets a smaller frequency dividing rate, as the ratio is smaller in a voltage control oscillator circuit.

8. The oscillator as set forth in claim 6, further comprising:
a memory section for storing a relation between the selected voltage control oscillator circuit and the frequency dividing rate of the frequency divider.

9. An integrated circuit, comprising:
an oscillator, which includes (a) a plurality of voltage control oscillator circuits, each of whose oscillation frequency varies, according to a control voltage, between a lower limit frequency and an upper limit frequency; and (b) a selection circuit for selecting an arbitrary voltage control oscillator circuit from the voltage control oscillator circuits, two or more of the voltage control oscillator circuits being different in terms of a ratio of (i) a difference between the upper limit frequency and the lower limit frequency, to (ii) an intermediate frequency between the upper limit frequency and the lower limit frequency.

10. A communication apparatus, comprising:
an oscillator, which includes (a) a plurality of voltage control oscillator circuits, each of whose oscillation frequency varies, according to a control voltage, between a lower limit frequency and an upper limit frequency; and (b) a selection circuit for selecting an arbitrary voltage control oscillator circuit from the voltage control oscillator circuits, two or more of the voltage control oscillator circuits being different in terms of a ratio of (i) a difference between the upper limit frequency and the lower limit frequency, to (ii) an intermediate frequency between the upper limit frequency and the lower limit frequency.
